(19) United States
(12) Patent Application Publication
(10) Pub. No.: US 2022/0248542 A1
(43) Pub. Date: Aug. 4, 2022

(54) IN-VEHICLE DISPLAY DEVICE

(71) Applicant: Mitsubishi Electric Corporation, Tokyo (JP)

(72) Inventor: Hideyuki HIROTA, Tokyo (JP)

(73) Assignee: Mitsubishi Electric Corporation, Tokyo (JP)

(21) Appl. No.: 17/616,507

(22) PCT Filed: Jul. 8, 2019
(86) PCT No.: PCT/JP2019/026944

§ 371 Date: Dec. 3, 2021

(51) Int. Cl. H05K 5/00; H05K 5/03; H05K 5/04

(52) U.S. Cl. CPC H05K 5/0017; H05K 5/03; B60R 11/0235; H05K 5/0008; H05K 5/04

(57) ABSTRACT

The display unit includes a display and a cover lens fixed to a front face of the display. A holder is a rigid body disposed on a rear side of the display unit and fixed to the display unit. A rear panel is a box having an opening, and the opening is covered with the cover lens in a state where the display and the holder are housed internally. Further, the rear panel is fixed to the holder.

### TECHNICAL FIELD

The present invention relates to an in-vehicle display device.

### BACKGROUND ART

The conventional display device described in Patent Literature 1 includes a front panel, a holder, a touch panel, a display, a placement panel, and a rear panel in order from the front. The frame-shaped front panel having an open front face is coupled to the rear panel to constitute a housing. The frame-shaped holder having an open front face, the touch panel, the display, and the placement panel are housed in the housing.

### CITATION LIST

### Patent Literatures

Patent Literature 1: JP 2012-63473 A

### SUMMARY OF INVENTION

### Technical Problem

In the conventional display device as described in Patent Literature 1, a frame such as a front panel is present on the front face, and thus the appearance of the display device is deteriorated.

The present invention has been made to solve the above problem, and an object of the present invention is to provide an in-vehicle display device in which no frame is present on the front face.

### Solution to Problem

An in-vehicle display device according to the present invention includes: a display unit including a display and a cover lens fixed to a front face of the display; a holder having rigidity, the holder being disposed on a rear side of the display unit and fixed to the display unit; and a rear panel in a box shape having an opening, the rear panel being fixed to the holder with the opening covered with the cover lens in a state of internally housing the display and the holder.

### Advantageous Effects of Invention

According to the present invention, since the housing is formed by a cover lens and a rear panel, it is possible to provide an in-vehicle display device in which no frame is present on the front face.

### BRIEF DESCRIPTION OF DRAWINGS

FIG. 1 is an exploded perspective view illustrating a configuration example of an in-vehicle display device according to a first embodiment.

FIG. 2 is an external perspective view illustrating a configuration example of the in-vehicle display device according to the first embodiment.

FIG. 3 is a front view illustrating a configuration example of the in-vehicle display device according to the first embodiment.

FIG. 4 is a cross-sectional view of the in-vehicle display device according to the first embodiment taken along line A-A in FIG. 3.

FIG. 5 is an exploded perspective view illustrating a configuration example of the in-vehicle display device as a reference example for helping to understand the in-vehicle display device according to the first embodiment.

FIG. 6 is an external perspective view illustrating a configuration example of the in-vehicle display device as a reference example for helping to understand the in-vehicle display device according to the first embodiment.

FIG. 7 is a front view illustrating a configuration example of the in-vehicle display device as a reference example for helping to understand the in-vehicle display device according to the first embodiment.

FIG. 8 is a cross-sectional view of the in-vehicle display device as a reference example taken along line B-B in FIG. 7.

FIG. 9 is a cross-sectional view illustrating an example in which a cover lens and a holder are adhesively fixed to each other in a second embodiment.

FIG. 10 is a cross-sectional view illustrating a modification of an in-vehicle display device according to the second embodiment.

FIG. 11 is an exploded perspective view illustrating an example in which a display and a holder are fixed to each other by screwing in a third embodiment.

FIG. 12 is a cross-sectional view illustrating a configuration example of an in-vehicle display device illustrated in FIG. 11.

FIG. 13 is a cross-sectional view illustrating an example in which a holder and a rear panel are fixed to each other by fitting them in a fourth embodiment.

FIG. 14 is a cross-sectional view illustrating an example in which a holder and a rear panel are fixed to each other by screwing in a fifth embodiment.

### DESCRIPTION OF EMBODIMENTS

In order to explain this invention in more detail, some modes for carrying out this invention will be described below with reference to the accompanying drawings.

### First Embodiment

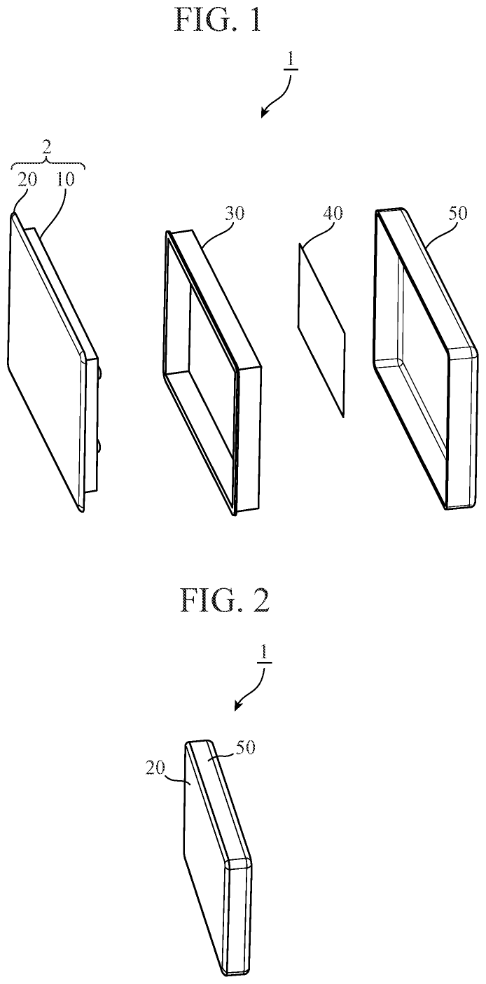

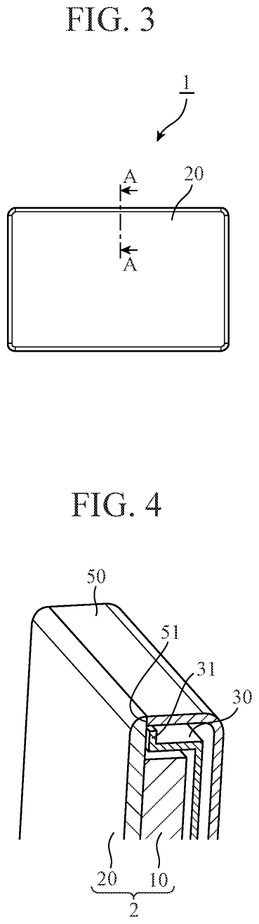

FIG. 1 is an exploded perspective view illustrating a configuration example of an in-vehicle display device 1 according to the first embodiment. FIG. 2 is an external perspective view illustrating a configuration example of the in-vehicle display device 1 according to the first embodiment. FIG. 3 is a front view illustrating a configuration example of the in-vehicle display device 1 according to the first embodiment. FIG. 4 is a cross-sectional view of the in-vehicle display device 1 according to the first embodiment taken along line A-A in FIG. 3.

The in-vehicle display device 1 includes a display 10, a cover lens 20, a holder 30, and a rear panel 50. The display 10 includes liquid crystal display, organic electro luminescence (EL) display, or the like. The transparent cover lens 20 is adhesively fixed to the front face, that is, a display surface of the display 10 by an adhesive member (not illustrated). The display 10 and the cover lens 20 constitute a display unit 2.

The holder 30 is a sheet metal component formed by processing a sheet metal or a die-cast component manufactured by die-casting, has rigidity, and is hardly thermally deformed. The holder 30 is disposed on a rear side of the display unit 2 and is fixed to the display unit 2. A specific example of a method for fixing the holder 30 and the display unit 2 is described in second and third embodiments.

The rear panel 50 is a housing for appearance design constituting the rear face of the in-vehicle display device 1. The rear panel 50 is a box made of a resin member or the like, and is fixed to the holder 30. A specific example of a method for fixing the rear panel 50 and the holder 30 to each other is described in fourth and fifth embodiments. The opening of the rear panel 50 is covered with the cover lens 20. The rear panel 50 and the cover lens 20 constitute a housing of the in-vehicle display device 1.

The control board 40 is a circuit board for controlling the display 10. The control board 40 is fixed to the rear face of the holder 30 by screwing (not illustrated) or the like.

Note that illustration and description of the control board 40 will be omitted below.

The display 10 and the holder 30 are housed in the rear panel 50. The opening of the rear panel 50 is covered with the cover lens 20. Therefore, as illustrated in FIG. 2, only the cover lens 20 and the rear panel 50 are components constituting the external appearance of the in-vehicle display device 1. Further, as illustrated in FIG. 3, only the cover lens 20 is present on the front face of the in-vehicle display device 1, and no frame is present. Therefore, the in-vehicle display device 1 has better appearance than that in the case where a frame is present on the front face.

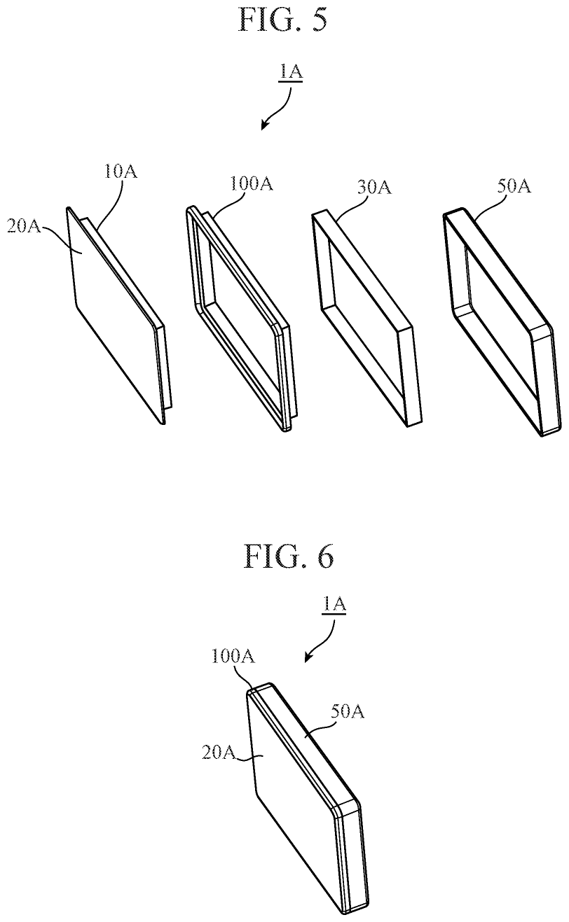

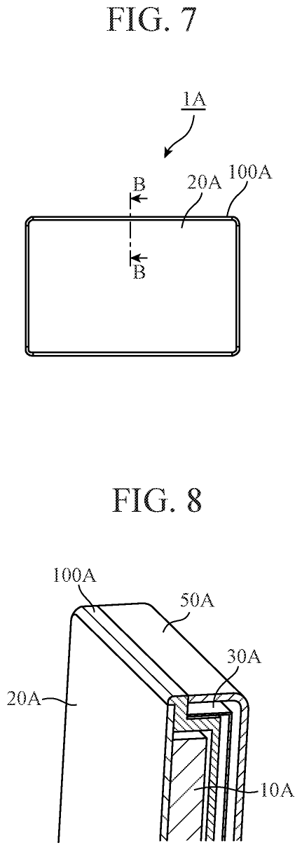

FIG. 5 is an exploded perspective view illustrating a configuration example of an in-vehicle display device 1A as a reference example for helping to understand the in-vehicle display device 1 according to the first embodiment. FIG. 6 is an external perspective view illustrating a configuration example of the in-vehicle display device 1A as a reference example for helping to understand the in-vehicle display device 1 according to the first embodiment. FIG. 7 is a front view illustrating a configuration example of the in-vehicle display device 1A as a reference example for helping to understand the in-vehicle display device 1 according to the first embodiment. FIG. 8 is a cross-sectional view of the in-vehicle display device 1A as a reference example taken along line B-B in FIG. 7.

The in-vehicle display device 1A as a reference example includes a display 10A, a cover lens 20A, a holder 30A, a rear panel 50A, and a resin frame 100A. In the reference example, the resin frame 100A and the cover lens 20A are fixed to each other. The peripheral edge portion of the resin frame 100A is in a state sandwiched between the cover lens 20A and the rear panel 50A. Therefore, as illustrated in FIG. 6, the components constituting the external appearance of the in-vehicle display device 1A are three components of the cover lens 20A, the rear panel 50A, and the resin frame 100A. Further, as illustrated in FIG. 7, not only the cover lens 20 but also the peripheral edge portion of the resin frame 100A shown as a frame is present on the front face of the in-vehicle display device 1A. Therefore, the in-vehicle display device 1A is inferior in appearance to the in-vehicle display device 1.

Temperature changes drastically in a vehicle in which the in-vehicle display device 1 and the in-vehicle display device 1A are used. In addition, the in-vehicle display device 1 and the in-vehicle display device 1A receive external force caused by vibration or the like of the vehicle. Therefore, when the resin frame 100A is deformed by heat or external force and a load is applied to the cover lens 20A, color unevenness occurs in the display 10A adhesively fixed to the cover lens 20A. On the other hand, since the resin frame 100A is not present in the in-vehicle display device 1, color unevenness of the display 10 does not occur. Further, the number of components of the in-vehicle display device 1 is smaller than that of the in-vehicle display device 1A.

As described above, the in-vehicle display device 1 according to the first embodiment includes the display unit 2, the holder 30, and the rear panel 50. The display unit 2 includes the display 10 and the cover lens 20 fixed to a front face of the display 10. The holder 30 is a rigid body disposed on a rear side of the display unit 2 and fixed to the display unit 2. The rear panel 50 is a box having an opening, and the opening is covered with the cover lens 20 in a state where the display 10 and the holder 30 are housed internally. Further, the rear panel 50 is fixed to the holder 30. Since the housing of the in-vehicle display device 1 is formed by the cover lens 20 and the rear panel 50, it is possible to provide the in-vehicle display device 1 in which no frame is present on the front face.

Further, according to the first embodiment, since the holder 30 is a sheet metal component or a die-cast component, the holder is hardly thermally deformed.

Further, according to the first embodiment, the in-vehicle display device 1 includes the control board 40 that is fixed to the rear face of the holder 30 and controls display of the display 10. Since the control board 40 is fixed to the holder 30 having rigidity, the control board is hardly affected by heat and external force. In addition, the control board 40 can use the holder 30 as a ground.

### Second Embodiment

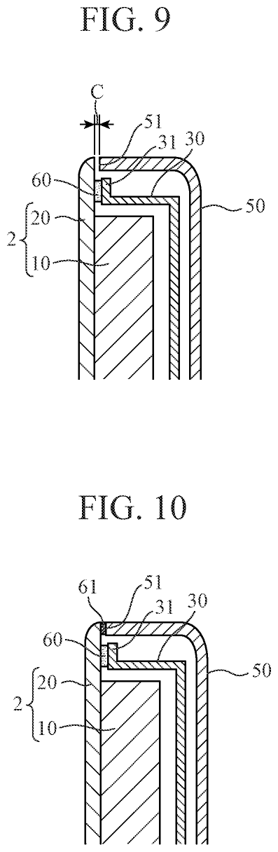

In the second embodiment, a method for fixing a display unit 2 and a holder 30 to each other will be described with reference to FIGS. 9 and 10. In FIGS. 9 and 10, the same or corresponding parts as those in FIGS. 1 to 4 are denoted by the same reference numerals, and description thereof is omitted.

FIG. 9 is a cross-sectional view illustrating an example in which a cover lens 20 and the holder 30 are adhesively fixed to each other in the second embodiment. A cross section in FIG. 9 corresponds to a cross section obtained by cutting the in-vehicle display device 1 according to the second embodiment along line A-A in FIG. 3. In the example of FIG. 9, an open end 31 of the holder 30 and the rear face of the cover lens 20 are adhesively fixed to each other by an adhesive member 60, whereby the holder 30 and the display unit 2 are fixed to each other.

In the in-vehicle display device 1 of the second embodiment, the cover lens 20 and the rear panel 50 are fixed to the holder 30, and the cover lens 20 and the rear panel 50 are not directly fixed to each other. Therefore, even if the resin rear panel 50 is deformed by heat or external force, no load is applied to the cover lens 20 that is not fixed to the rear panel 50, so that color unevenness of the display 10 does not occur. An open end 51 of the rear panel 50 may be disposed with a gap C from the rear face of the cover lens 20. Due to the presence of the gap C, it is possible to more reliably prevent a load from being applied to the cover lens 20 when the rear panel 50 is deformed by heat or external force.

FIG. 10 is a cross-sectional view illustrating a modification of the in-vehicle display device 1 according to the second embodiment. In the example of FIG. 9, the gap C exists between the open end 51 of the rear panel 50 and the rear face of the cover lens 20, but in the example of FIG. 10, a second elastic body 61 is disposed in the gap C. The second elastic body 61 is made of nonwoven fabric, rubber, or the like. Since the second elastic body 61 closes the gap C, the internal structure of the in-vehicle display device 1 is not exposed, and the appearance design is increased. In addition, the load applied to the cover lens 20 when the rear panel 50 is deformed by heat or external force can be reduced by the second elastic body 61.

### Third Embodiment

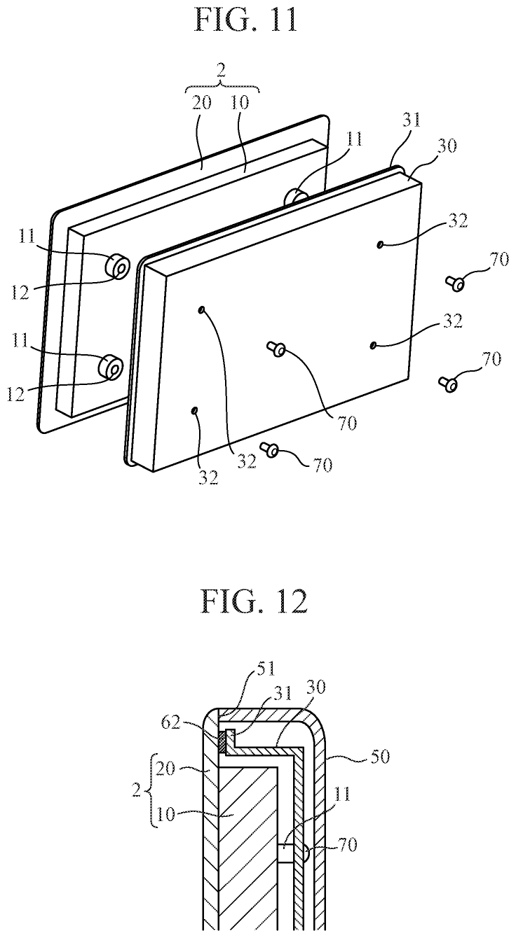

In the third embodiment, a method for fixing a display unit 2 and a holder 30 to each other will be described with reference to FIGS. 11 and 12. Note that, in FIGS. 11 and 12, the same or corresponding parts as those in FIGS. 1 to 4, 9, and 10 are denoted by the same reference numerals, and description thereof is omitted.

FIG. 11 is an exploded perspective view illustrating an example in which a display 10 and the holder 30 are fixed to each other by screwing in the third embodiment. The rear face of the display 10 is made of a metal member, and a plurality of screw bosses 11 are provided on the rear face. Each screw boss 11 is provided with a screw fastening hole 12 for fastening a screw 70. The holder 30 is provided with a plurality of screw through holes 32 through which the plurality of screws 70 pass. Each of the screws 70 passes through the screw through hole 32 of the holder 30 and is fastened to the screw fastening hole 12 of the display 10. Thus, the holder 30 and the display unit 2 are fixed to each other.

FIG. 12 is a cross-sectional view illustrating a configuration example of the in-vehicle display device 1 illustrated in FIG. 11. A cross section in FIG. 12 corresponds to a cross section obtained by cutting the in-vehicle display device 1 according to the third embodiment along line A-A in FIG. 3. As illustrated in the cross-sectional view of FIG. 12, a first elastic body 62 may be disposed between the open end 31 of the holder 30 and the rear face of the cover lens 20. The first elastic body 62 is made of nonwoven fabric, rubber, or the like. The first elastic body 62 reduces a load applied to the cover lens 20 when the holder 30 is pushed toward the cover lens 20 when the screw 70 is fastened.

Note that, in the example of FIG. 12, similarly to the example of FIG. 9, a gap C may exist between the open end 51 of the rear panel 50 and the rear face of the cover lens 20, or a second elastic body 61 that closes the gap C may be disposed.

### Fourth Embodiment

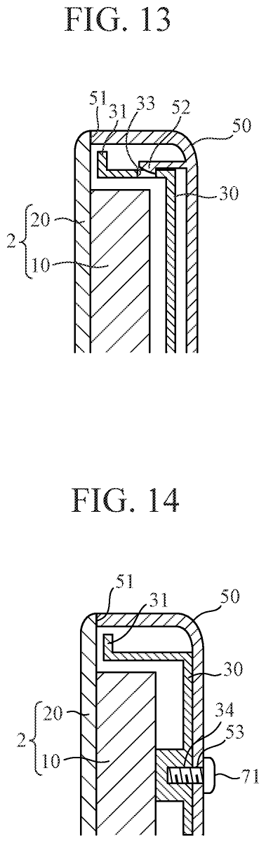

In the fourth embodiment, a method for fixing a holder 30 and a rear panel 50 to each other will be described with reference to FIG. 13. Note that, in FIG. 13, the same or corresponding parts as those in FIGS. 1 to 4 and 9 to 12 are denoted by the same reference numerals, and description thereof is omitted.

FIG. 13 is a cross-sectional view illustrating an example in which the holder 30 and the rear panel 50 are fixed to each other by fitting them to each other in the fourth embodiment. A cross section in FIG. 13 corresponds to a cross section obtained by cutting the in-vehicle display device 1 according to the fourth embodiment along line A-A in FIG. 3. A plurality of fitting claws 52 are provided inside the rear panel 50. Fitting holes 33 are respectively provided at positions facing the fitting claws 52 in the holder 30. The fitting claw 52 of the rear panel 50 is fitted into the fitting hole 33 of the holder 30, whereby the holder 30 and the rear panel 50 are fixed to each other.

Note that, in the example of FIG. 13, similarly to the example of FIG. 9, a gap C may exist between the open end 51 of the rear panel 50 and the rear face of the cover lens 20, or a second elastic body 61 that closes the gap C may be disposed.

Further, in the example of FIG. 13, the holder 30 may be adhesively fixed to the cover lens 20 by the adhesive member 60 similarly to the example of FIG. 9. Alternatively, similarly to the example of FIG. 12, the holder 30 may be fixed to the display 10 with the screws 70. In the case of screw fixing, similarly to the example of FIG. 12, the first elastic body 62 may be disposed between the open end 31 of the holder 30 and the rear face of the cover lens 20.

### Fifth Embodiment

In the fifth embodiment, a method for fixing a holder 30 and a rear panel 50 to each other will be described with reference to FIG. 14. Note that, in FIG. 14, the same or corresponding parts as those in FIGS. 1 to 4 and 9 to 12 are denoted by the same reference numerals, and description thereof is omitted.

FIG. 14 is a cross-sectional view illustrating an example in which the holder 30 and the rear panel 50 are fixed to each other by screwing in the fifth embodiment. A cross section in FIG. 14 corresponds to a cross section obtained by cutting the in-vehicle display device 1 according to the fifth embodiment along line A-A in FIG. 3. The rear panel 50 is provided with a plurality of screw through holes 53 through which the plurality of screws 71 pass. The holder 30 is provided with a plurality of screw fastening holes 34 for fastening the plurality of screws 71 by burring or the like. Each of the screws 71 passes through the screw through hole 53 of the rear panel 50 and is fastened to the screw fastening hole 34 of the holder 30.

Note that, in the example of FIG. 14, similarly to the example of FIG. 9, a gap C may exist between the open end 51 of the rear panel 50 and the rear face of the cover lens 20, or a second elastic body 61 that closes the gap C may be disposed.

Further, in the example of FIG. 14, the holder 30 may be adhesively fixed to the cover lens 20 by the adhesive member 60 similarly to the example of FIG. 9. Alternatively, similarly to the example of FIG. 12, the holder 30 may be fixed to the display 10 with the screws 70. In the case of screw fixing, similarly to the example of FIG. 12, the first elastic body 62 may be disposed between the open end 31 of the holder 30 and the rear face of the cover lens 20.

Note that, within the scope of the present invention, free combinations of the respective embodiments, deformation of any component of each embodiment, or omission of any component of each embodiment are possible.

### INDUSTRIAL APPLICABILITY

An in-vehicle display device according to the present invention is suitable for use in an in-vehicle display device such as a car navigation device or a center display installed on a dashboard.

### REFERENCE SIGNS LIST

1, 1A: in-vehicle display device, 2: display unit, 10, 10A: display, 11: screw boss, 12: screw fastening hole, 20, 20A: cover lens, 30, 30A: holder, 31: open end, 32: screw through hole, 33: fitting hole, 34: screw fastening hole, 40: control board, 50, 50A: rear panel, 51: open end, 52: fitting claw, 53: screw through hole, 60: adhesive member, 61: second elastic body, 62: first elastic body, 70, 71: screw, 100A: resin frame, C: gap.

1. An in-vehicle display device, comprising:
a display unit including a display and a cover lens fixed to a front face of the display;
a holder having rigidity, the holder being disposed on a rear side of the display unit and fixed to the display unit; and
a rear panel in a box shape having an opening, the rear panel being fixed to the holder with the opening covered with the cover lens in a state of internally housing the display and the holder.

2. The in-vehicle display device according to claim 1, wherein the holder is a box internally housing the display, and an open end of the holder is adhesively fixed to a rear face of the cover lens.

3. The in-vehicle display device according to claim 1, wherein the holder is a box internally housing the display, and a first elastic body is disposed between an open end of the holder and a rear face of the cover lens.

4. The in-vehicle display device according to claim 1, wherein an open end of the rear panel is disposed with a gap from a rear face of the cover lens.

5. The in-vehicle display device according to claim 4, wherein a second elastic body is disposed in the gap between the open end of the rear panel and the rear face of the cover lens.

6. The in-vehicle display device according to claim 1, wherein the holder is a sheet metal component or a die-cast component.

7. The in-vehicle display device according to claim 1, further comprising a control board that is fixed to a rear face of the holder and controls display of the display.

8. The in-vehicle display device according to claim 1, wherein the holder is fixed to a rear face of the display by screwing.

9. The in-vehicle display device according to claim 1, wherein the rear panel is fixed to the holder by fitting.

10. The in-vehicle display device according to claim 1, wherein the rear panel is fixed to the holder by screwing.
